(19) United States
(12) Patent Application Publication
(10) Pub. No.: US 2006/0108618 A1
(43) Pub. Date: May 25, 2006

(54) CMOS image sensor having buried channel MOS transistors

(75) Inventors: Jung-Chak Ahn, Suwon-si (KR); Tetsuo Asaba, Suwon-si (KR); Yi-Tae Kim, Suwon-si (KR); Jung-Yeon Kim, Busan (KR); Sung-In Hwang, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/280,695

(22) Filed: Nov. 16, 2005

(30) Foreign Application Priority Data
Nov. 25, 2004 (KR) 2004-97671

(51) Int. Cl. H01L 31/113

(52) U.S. Cl. 257/292

(57) ABSTRACT

A CMOS image sensor having buried channel MOS transistors is disclosed. The CMOS image sensor includes a photo converting device and a source follower transistor. The photo converting device generates a current signal and changes a voltage of a floating node in response to energy of an incident light. The source follower transistor has a source region doped with a first conductivity-type material, a drain region doped with the first conductivity-type material, a gate region doped with a second conductivity-type material that is complementary to the first conductivity-type material, and a buried channel having the first conductivity-type material. The buried channel is formed between the source region and the drain region and under the gate region.

### CROSS-REFERENCE TO RELATED APPLICATION

This application claims priority under 35 U.S.C. § 119 to Korean Patent Application No. 2004-97671, filed on Nov. 25, 2004, the disclosure of which is incorporated by reference herein in its entirety.

### BACKGROUND OF THE INVENTION

1. Technical Field

The present invention relates to a complementary metal oxide semiconductor (CMOS) image sensor, and more particularly, to a CMOS image sensor having buried channel metal-oxide-semiconductor (MOS) transistors.

2. Discussion of the Related Art

A CMOS image sensor has found increasing use in battery-dependent portable applications such as laptop computers, hand-held scanners and video cell phones because unlike a charge-coupled device (CCD), the CMOS image sensor can operate in low voltage applications, consumes less power than the CCD and has a low fabrication cost.

FIG. 1 is a block diagram showing a general CMOS active pixel sensor circuit. Referring to FIG. 1, the CMOS active pixel sensor circuit includes a control circuit 400, a row decoder 100, a row driver 200, a pixel array 300, a column decoder 600 and a column driver 500.

The pixel array 300 includes a plurality of pixels arranged in a predetermined number of columns and rows. The pixels of each row in the pixel array 300 are turned on at the same time by a row-selecting line, and the pixels of each column are selectively output by a column selecting line.

A plurality of row selecting lines and column selecting lines are arranged in the pixel array 300. The row-selecting lines are selectively activated by the row driver 200 in response to an output signal of the row decoder 100, and the column selecting lines are selectively activated by the column driver 500 in response to an output signal of the column decoder 600. The control circuit 400 controls the decoders 100 and 600 to select appropriate row and column lines. Accordingly, row and column addresses are provided by the decoders 100 and 600 for each pixel in the pixel array 300.

FIG. 2 is a circuit diagram showing an example of a CMOS image sensor for constructing a pixel array in the CMOS active pixel sensor circuit of FIG. 1. Referring to FIG. 2, the CMOS image sensor includes a photo diode 11, a transfer transistor 13, a reset transistor 15, a source follower transistor 17 and a row-selecting transistor 18. Further, the CMOS image sensor includes a load transistor 19 for electrically connecting an output line LO to a low supply voltage VSS. Each of the transistors 13, 15, 17, 18 and 19 is a basic NMOS transistor.

As shown in FIG. 2, when light is applied to the photo diode 11, a current flowing through the photo diode 11 is changed in response to an intensity of the light. When the current flowing through the photo diode 11 is changed, a voltage of a floating node NF and an output signal PO transferred to the output line LO are changed. The output signal PO is image data.

In the CMOS image sensor of FIG. 2, flicker noise may be generated by the transistors 13, 15, 17, 18 and 19 because the transistors 13, 15, 17, 18 and 19 are basic NMOS transistors.

In U.S. Pat. No. 6,630,701, the use of buried channel NMOS transistors is disclosed for constructing a CMOS image sensor. For example, U.S. Pat. No. 6,630,701 discloses a technique for decreasing a charge loss to a substrate underlying the NMOS transistors by lightly doping a channel region of the NMOS transistors with the same impurities found in their source and drain areas.

However, this technique does not decrease enough of the flicker noise generated by the NMOS transistors. Further, the CMOS image sensor of U.S. Pat. No. 6,630,701 may have a very low threshold voltage and a large off current. Therefore, erroneous signals may be output from the CMOS image sensor.

FIG. 3A and FIG. 3B are cross-sectional views of a buried channel NMOS transistor and a buried channel PMOS transistor disclosed in U.S. Pat. No. 6,621,125. The buried channel NMOS and PMOS transistors of FIG. 3A and FIG. 3B are for use with an electrostatic discharge protection circuit capable minimizing the effect of a current flowing close to a gate oxide layer on the electrostatic discharge protection circuit.

Referring to FIG. 3A, the buried channel NMOS transistor includes a P type substrate 30, a P+ ion doped region 32, a first N+ doped region 34, a second N+ doped region 36 and an N doped region 38. The P+ ion doped region 32 is formed above the P type substrate 30, and functions as a gate terminal. The first N+ doped region 34 is formed in the P type substrate 30 and functions as a source region, and the second N+ doped region 36 is formed in the P type substrate 30 and functions as a drain region. The N doped region 38 is formed between the first N+ doped region 34 and the second N+ doped region 36 in the P type substrate 30 and under the P+ ion doped region 32.

Referring to FIG. 3B, the buried channel PMOS transistor includes an N type substrate 40, an N+ ion doped region 42, a first P+ doped region 44, a second P+ doped region 46 and a P doped region 48. The N+ ion doped region 42 is formed above the N type substrate 40, and functions as a gate terminal. The first P+ doped region 44 is formed in the N type substrate 40 and functions as a source region, and the second P+ doped region 46 is formed in the N type substrate 40 and functions as a drain region. The P doped region 48 is formed between the first P+ doped region 44 and the second P+ doped region 46 in the N type substrate 40 and under the N+ ion doped region 42.

In U.S. Pat. No. 6,245,607 a buried channel MOS transistor that may decrease flicker noise is disclosed. As disclosed in U.S. Pat. No. 6,245,607, the buried channel MOS transistor is formed by implanting a channel layer in a bulk region between a source region and a drain region, rather than on the surface of a substrate adjacent to a gate insulator layer, by placing a gate oxide on the surface of the substrate immediately above the channel layer and doping a gate electrode of a conductive material with a material having a conductivity opposite that of the source/drain deposited on the gate oxide above the channel region.

Although a variety of techniques have been developed for reducing flicker noise in a CMOS image sensor, a need exists for a CMOS image sensor that reduces flicker noise and enhances the accuracy of image data output therefrom.

### SUMMARY OF THE INVENTION

In an embodiment of the present invention, a CMOS image sensor includes a photo converting device and a source follower transistor. The photo converting device generates a current signal and changes a voltage of a floating node in response to energy of an incident light. The source follower transistor has a source region doped with a first conductivity-type material, a drain region doped with the first conductivity-type material, a gate region doped with a second conductivity-type material that is complementary to the first conductivity-type material, and a buried channel having the first conductivity-type material. The buried channel is formed between the source region and the drain region and under the gate region. Further, the source follower transistor amplifies the voltage of the floating node to generate a first signal.

The buried channel may be doped with a first conductivity-type material, wherein the buried channel may be doped at a dopant concentration less than a dopant concentration of the source region or the drain region. The buried channel may be formed by using an ion implantation technique.

The first conductivity-type material may be an N type material and the second conductivity-type material may be a P type material. The first conductivity-type material may be a P type material and the second conductivity-type material may be an N type material. The first conductivity-type material may be an element that belongs to group V of the periodic table of elements, and the second conductivity-type material may be an element that belongs to group III of the periodic table of elements.

In another embodiment of the present invention, a CMOS image sensor includes a photo converting device and first through fifth transistors. The photo converting device is configured to generate a current signal and change a voltage of a floating node in response to energy of an incident light. The first through fifth transistors each has a source region doped with a first conductivity-type material, a drain region doped with the first conductivity-type material, a gate region doped with a second conductivity-type material that is complementary to the first conductivity-type material, and a buried channel having the first conductivity-type material, the buried channel being formed between the source region and the drain region and under the gate region.

The first transistor amplifies the voltage of the floating node to generate a first signal, the second transistor outputs the first signal to an output terminal in response to a row-selecting signal, the third transistor transfers an output signal of the photo converting device to the floating node in response to a transfer signal, the fourth transistor resets the floating node in response to a reset signal and the fifth transistor electrically connects an output line to a low supply voltage.

### BRIEF DESCRIPTION OF THE DRAWINGS

The foregoing and other features of the invention will become more apparent from the descriptions of exemplary embodiments of the invention as illustrated in the accompanying drawings. The drawings are not necessarily to scale, with emphasis instead being placed upon illustrating the principles of the invention. Like reference characters refer to like elements throughout the drawings.

FIG. 1 is a block diagram showing a general CMOS active pixel sensor circuit.

FIG. 2 is a circuit diagram showing an example of a CMOS image sensor for constructing a pixel array in the CMOS active pixel sensor circuit of FIG. 1.

FIG. 3A and FIG. 3B are cross-sectional views of a general buried channel NMOS transistor and a general buried channel PMOS transistor respectively.

FIG. 4 is a circuit diagram showing a CMOS image sensor according to an exemplary embodiment of the present invention.

FIG. 5 is a cross-sectional view of the CMOS image sensor of FIG. 4 when implemented in a semiconductor integrated circuit.

FIG. 6 is a cross-sectional view of two transistors of the CMOS image sensor shown in FIG. 5.

FIG. 7 is graph showing potential profiles of a source follower transistor in a CMOS image sensor that includes buried channel MOS transistors according to an exemplary embodiment of the present invention and potential profiles of a source follower transistor in a CMOS image sensor that includes basic NMOS transistors.

FIG. 8 is a simulation diagram illustrating flicker noise for a source follower transistor of a CMOS image sensor that includes buried channel MOS transistors according to an exemplary embodiment of the present invention and flicker noise for a source follower transistor of a CMOS image sensor that includes basic MOS transistors.

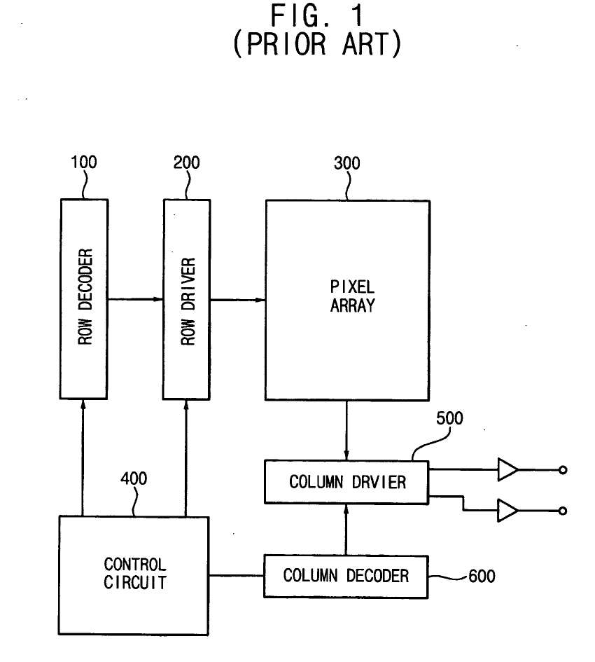

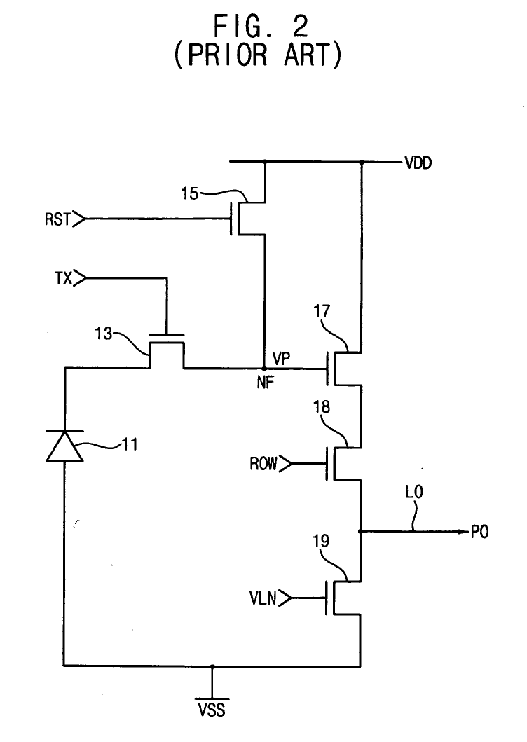

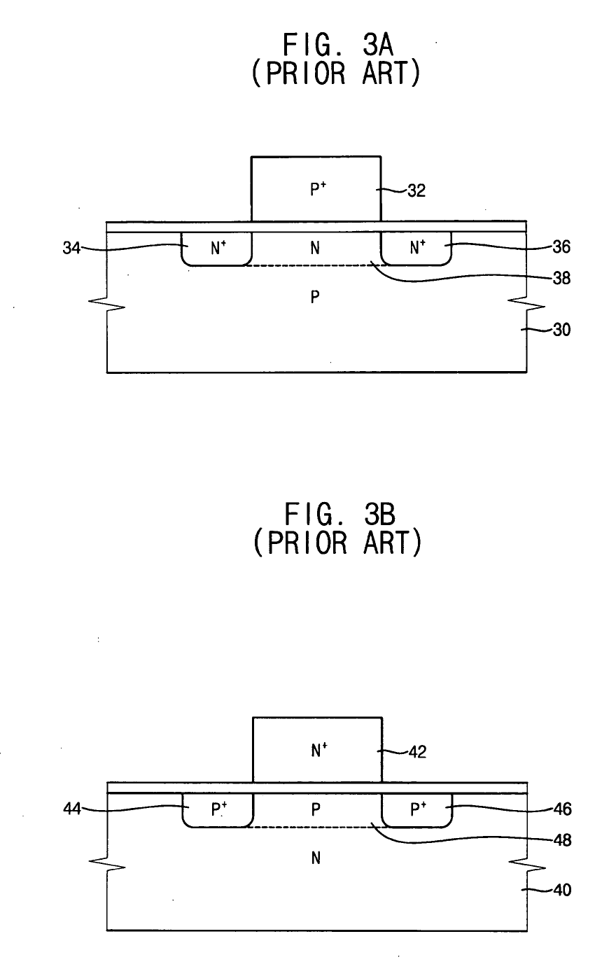

### DESCRIPTION OF EXEMPLARY EMBODIMENTS

Detailed exemplary embodiments of the present invention are disclosed herein. However, specific structural and functional details disclosed herein are merely presented for purposes of describing the exemplary embodiments of the present invention.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

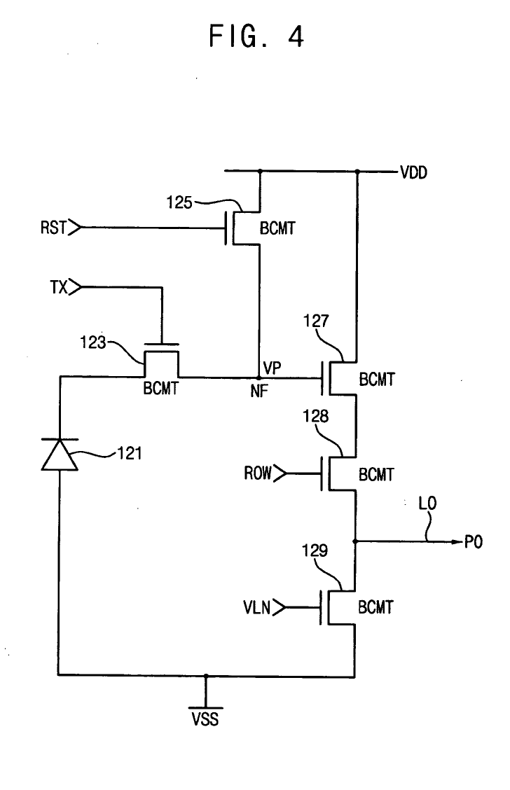

FIG. 4 is a circuit diagram showing a CMOS image sensor according to an exemplary embodiment of the present invention. Referring to FIG. 4, the CMOS image sensor includes a photo diode 121, a transfer transistor 123, a reset transistor 125, a source follower transistor 127 and a row-selecting transistor 128. Further, the CMOS image sensor includes a load transistor 129 for electrically connecting an output line LO to a low supply voltage VSS.

The source follower transistor 127 is a buried channel CMOS transistor BCMT. The source follower transistor 127 has a source region doped with a first conductivity-type material, and a drain region doped with the first conductivity-type material. Further, the source follower transistor 127 has a gate region doped with a second conductivity-type material that is complementary to the first conductivity-type material, and a buried channel having the first conductivity-type material formed between the source region and the drain region and under the gate region. The source follower transistor 127 amplifies a voltage of a floating node NF. In addition to the source follower transistor 127, each of the transistors 123, 125, 128, 129 may be a buried channel CMOS transistor BCMT.

The operation of the CMOS image sensor of FIG. 4 will now be described.

As shown in FIG. 4, when light is applied to the photo diode 121, a current flowing through the photo diode 121 will be changed in response to an intensity of the light. When the current flowing through the photo diode 121 is changed, a voltage of the floating node NF and an output signal PO transferred to the output line LO are changed. The output signal PO is image data.

When a reset signal RST has a logic low state and a transfer signal TX has a logic high state, when a light is applied to the photo diode 121, a current flows through the photo diode 121. Because the reset signal RST is in the logic low state and the transfer signal TX is in the logic high state, the reset transistor 125 turns off and the transfer transistor 123 turns on. Therefore, the voltage of the floating node NF decreases. At this time, if a row-selecting signal ROW is in the logic high state, the row selecting transistor 128 turns on and a voltage VP of a gate terminal of the source follower transistor 127 is outputted to the output line LO. Before sensing the next image, the floating node NF is reset by the reset transistor 125. When the intensity of the light applied to the photo diode 121 becomes stronger, the voltage of the gate terminal of the source follower transistor 127 decreases and the output signal PO decreases.

As further shown in FIG. 4, the load transistor 129 is turned on in response to a voltage load signal VLN.

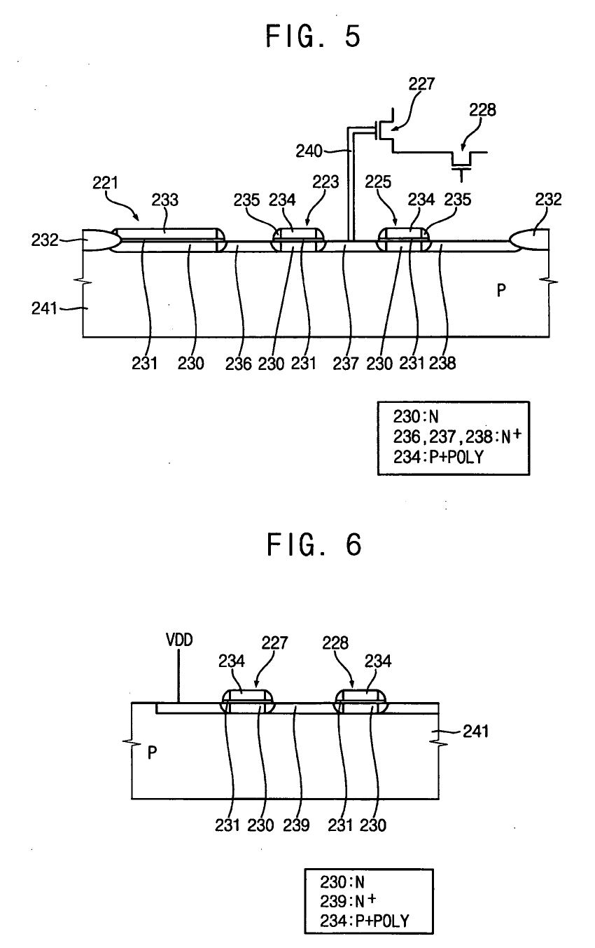

FIG. 5 is a cross-sectional view of the CMOS image sensor of FIG. 4 when implemented in a semiconductor integrated circuit, and FIG. 6 is a cross-sectional view of two transistors shown in FIG. 5.

Referring to FIG. 5, the CMOS image sensor is formed on a P well 241. The P well 241 may be a substrate or a well formed on a substrate. A field oxide layer 232 is formed on the P well 241 to isolate cells, for example, pixel cells, located therebetween. Three regions 236, 237 and 238 are doped with an N type material in the P well 241. The doped region 236 electrically connects a photo diode 221 to a transfer transistor 223.

An insulating layer 231 is formed between a photo gate 233 and a buried channel 230. Further, the insulating layer 231 is formed between a gate 234 of the transfer transistor 223 and the buried channel 230. In addition, the insulating layer 231 is formed between the gate 234 of a reset transistor 225 and the buried channel 230. The gate 234 of the transfer transistor 223 and the reset transistor 225 are formed with P+ poly silicon that is doped with a P type material of high concentration.

As further shown in FIG. 5, the buried channel region 230 is an N type doped region and is formed in the P well 241 and under the photo gate 233 of the photo diode 221, the transfer transistor 223 and the reset transistor 225. Each of the photo diode 221, the transfer transistor 223 and the reset transistor 225 has a spacer formed on the side of their gates 233 and 234. The three regions 236, 237 and 238 doped with an N type material are formed with N+ silicon doped with an N type material of high concentration, and function as a connection line as well as a source region and a drain region. The buried channel region 230 doped with an N type material has a lower doping concentration than the doping concentration of the three regions 236, 237 and 238. A source follower transistor 227 and a row-selecting transistor 228 are coupled to the region 237, which is a floating diffusion region, through a diffusion contact line 240.

The N type material may be comprised of an element that belongs to group V of the periodic table of elements, and the P type material may be comprised of an element that belongs to group III of the periodic table of elements. The buried channel may be formed by using an ion implantation technique.

Referring to FIG. 6, the source follower transistor 227 and the row-selecting transistor 228 may each be a buried CMOS transistor. In addition, the source follower transistor 227 and the row-selecting transistor 228 may be formed in a fashion similar to the transfer transistor 223 or the reset transistor 225 as shown in FIG. 5.

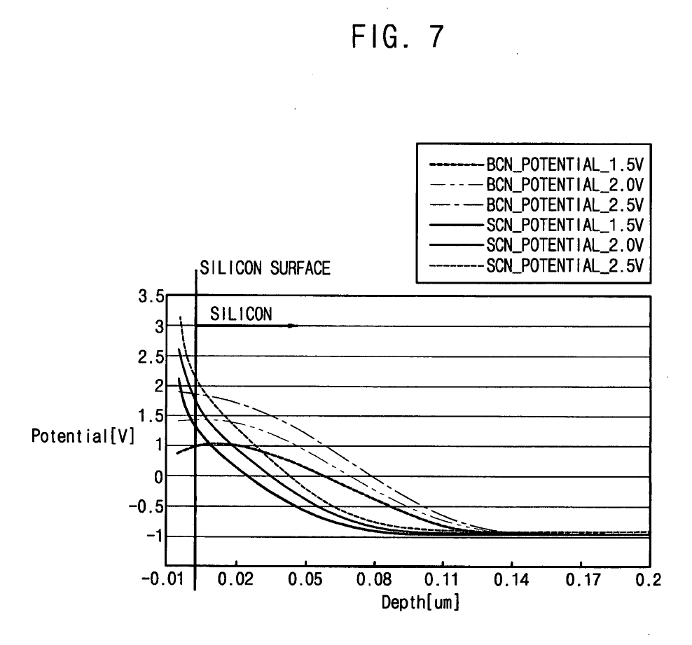

FIG. 7 is graph showing potential profiles of a source follower transistor in a CMOS image sensor that includes buried channel MOS transistors according to an exemplary embodiment of the present invention and potential profiles of a source follower transistor in a CMOS image sensor that includes basic NMOS transistors.

In FIG. 7, BCN_POTENTIAL_{—}1.5V represents the potential profile when 1.5V is applied to a gate of a buried channel MOS transistor, and SCN_POTENTIAL_{—}1.5V represents the potential profile when 1.5V is applied to a gate of a basic MOS transistor. BCN_POTENTIAL_{—}2.0V represents the potential profile when 2.0V is applied to the gate of the buried channel MOS transistor, and SCN_POTENTIAL_{—}2.0V represents the potential profile when 2.0V is applied to the gate of the basic MOS transistor. BCN_POTENTIAL_{—}2.5V represents the potential profile when 2.5V is applied to the gate of the buried channel MOS transistor, and SCN_POTENTIAL_{—}2.5V represents the potential profile when 2.5V is applied to the gate of the basic MOS transistor.

Referring to FIG. 7, the source follower transistor, which is a buried channel MOS transistor, has a maximum potential at a predetermined distance from the surface of a substrate on which it is formed, in contrast to that of the source follower transistor comprised of the basic MOS transistor. Thus, when a channel, which acts as a current path, is formed away from a gate insulator, the current flowing through the source follower transistor may be less affected by a state of the surface. In other words, the buried channel MOS transistor according to an exemplary embodiment of the present invention may have low flicker noise.

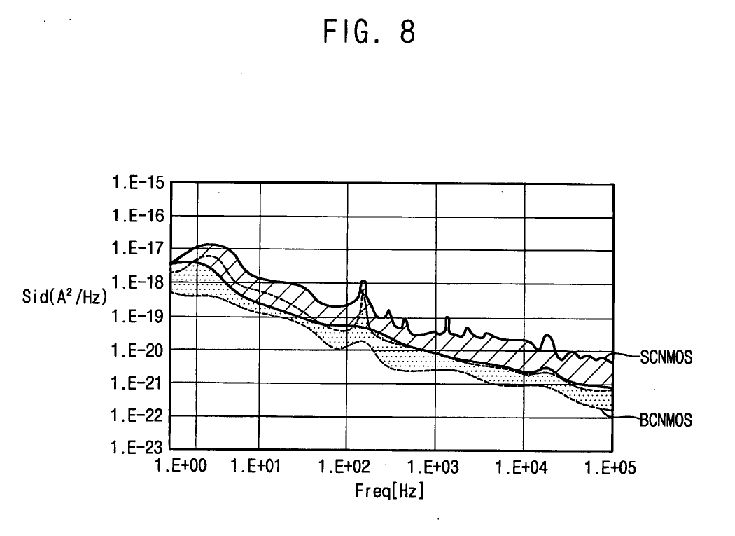

FIG. 8 is a simulation diagram illustrating flicker noise for a source follower transistor of a CMOS image sensor that includes buried channel MOS transistors according to an exemplary embodiment of the present invention and flicker noise for a source follower transistor of a CMOS image sensor that includes basic MOS transistors.

Referring to FIG. 8, it can be noted that the source follower transistor of the CMOS image sensor using a buried channel MOS transistor BCNMOS has a lower flicker noise than the source follower transistor of the CMOS image sensor using a basic MOS transistor SCNMOS.

Accordingly, by implementing the CMOS image sensor using the buried channel MOS transistor, the flicker noise of the CMOS image sensor may be decreased and an accuracy of image data outputted from the CMOS image sensor may be enhanced.

It is to be understood by one of ordinary skill in the art that although the above described CMOS image sensor includes buried channel NMOS transistors, buried channel PMOS transistors may be used in place of the buried channel NMOS transistors or in conjunction with the NMOS transistors.

While the exemplary embodiments of the present invention have been described in detail, it should be understood that various changes, substitutions and alterations can be made herein without departing from the scope of the invention as defined by appended claims.

What is claimed is:

1. A CMOS image sensor, comprising:
a photo converting device configured to generate a current signal and change a voltage of a floating node in response to energy of an incident light; and
a source follower transistor having a source region doped with a first conductivity-type material, a drain region doped with the first conductivity-type material, a gate region doped with a second conductivity-type material that is complementary to the first conductivity-type material, and a buried channel having the first conductivity-type material, the buried channel being formed between the source region and the drain region and under the gate region, wherein the source follower transistor amplifies the voltage of the floating node to generate a first signal.

2. The CMOS image sensor of claim 1, wherein the buried channel is doped with the first conductivity-type material, wherein the buried channel is doped at a dopant concentration less than a dopant concentration of the source region or the drain region.

3. The CMOS image sensor of claim 2, wherein the first conductivity-type material is an N type material and the second conductivity-type material is a P type material or the first conductivity-type material is a P type material and the second conductivity-type material is an N type material.

4. The CMOS image sensor of claim 3, wherein the first conductivity-type material is comprised of an element that belongs to group V of the periodic table of elements, and the second conductivity-type material is comprised of an element that belongs to group III of the periodic table of elements.

5. The CMOS image sensor of claim 1, further comprising:
a row-selecting transistor configured to output the first signal to an output terminal in response to a row-selecting signal.

6. The CMOS image sensor of claim 5, wherein the row-selecting transistor has a source region doped with the first conductivity-type material, a drain region doped with the first conductivity-type material, a gate region doped with the second conductivity-type material, and a buried channel having the first conductivity-type material formed between the source region and the drain region and under the gate region.

7. The CMOS image sensor of claim 6, wherein the buried channel is doped with the first conductivity-type material, wherein the buried channel is doped at a dopant concentration less than a dopant concentration of the source region or the drain region.

8. The CMOS image sensor of claim 7, wherein the first conductivity-type material is an N type material and the second conductivity-type material is a P type material or the first conductivity-type material is a P type material and the second conductivity-type material is an N type material.

9. The CMOS image sensor of claim 1, further comprising:
a transfer transistor configured to transfer an output signal of the photo converting device to the floating node in response to a transfer signal.

10. The CMOS image sensor of claim 9, wherein the transfer transistor has a source region doped with the first conductivity-type material, a drain region doped with the first conductivity-type material, a gate region doped with the second conductivity-type material, a buried channel having the first conductivity-type material formed between the source region and the drain region and under the gate region.

11. The CMOS image sensor of claim 10, wherein the buried channel is doped with the first conductivity-type material, wherein the buried channel is doped at a dopant concentration less than a dopant concentration of the source region or the drain region.

12. The CMOS image sensor of claim 11, wherein the first conductivity-type material is an N type material and the second conductivity-type material is a P type material or the first conductivity-type material is a P type material and the second conductivity-type material is an N type material.

13. The CMOS image sensor of claim 1, further comprising:
a reset transistor configured to reset the floating node in response to a reset signal.

14. The CMOS image sensor of claim 13, wherein the reset transistor has a source region doped with the first conductivity-type material, a drain region doped with the first conductivity-type material, a gate region doped with the second conductivity-type material, and a buried channel having the first conductivity-type material formed between the source region and the drain region and under the gate region.

15. The CMOS image sensor of claim 14, wherein the buried channel is doped with the first conductivity-type material, wherein the buried channel is doped at a dopant concentration less than a dopant concentration of the source region or the drain region.

16. The CMOS image sensor of claim 15, wherein the first conductivity-type material is an N type material and the second conductivity-type material is a P type material or the first conductivity-type material is a P type material and the second conductivity-type material is an N type material.

17. The CMOS image sensor of claim 1, wherein the photo-converting device is a photo diode.

18. A CMOS image sensor, comprising:
a photo converting device configured to generate a current signal and change a voltage of a floating node in response to energy of an incident light; and
first through fifth transistors each having a source region doped with a first conductivity-type material, a drain region doped with the first conductivity-type material, a gate region doped with a second conductivity-type material that is complementary to the first conductivity-type material, and a buried channel having the first conductivity-type material, the buried channel being formed between the source region and the drain region and under the gate region.

19. The CMOS image sensor of claim 18, wherein the first transistor amplifies the voltage of the floating node to generate a first signal, the second transistor outputs the first signal to an output terminal in response to a row-selecting signal, the third transistor transfers an output signal of the photo converting device to the floating node in response to a transfer signal, the fourth transistor resets the floating node in response to a reset signal and the fifth transistor electrically connects an output line to a low supply voltage.

20. The CMOS image sensor of claim 18, wherein the buried channels are doped with the first conductivity-type material, wherein the buried channels are doped at a dopant concentration less than a dopant concentration of the source regions or the drain regions.

21. The CMOS image sensor of claim 20, wherein the buried channels are formed by using an ion implantation technique.

22. The CMOS image sensor of claim 18, wherein the first conductivity-type material is an N type material and the second conductivity-type material is a P type material or the first conductivity-type material is a P type material and the second conductivity-type material is an N type material.

23. The CMOS image sensor of claim 18, wherein the first conductivity-type material is comprised of an element that belongs to group V of the periodic table of elements, and the second conductivity-type material is comprised of an element that belongs to group III of the periodic table of elements.
